(19) United States
(12) Patent Application Publication
(10) Pub. No.: US 2019/0331475 A1
(43) Pub. Date: Oct. 31, 2019

(54) BOUNDARY DETECTOR OF AN OPTICAL INSPECTION MACHINE

(71) Applicant: STEK CO., LTD, Taichung City (TW)

(72) Inventor: Ming-Sheng Chen, Taichung City (TW)

(21) Appl. No.: 15/967,565

(22) Filed: Apr. 30, 2018

(51) Int. Cl. G01B 11/06; G03F 1/84

(52) U.S. Cl. CPC G01B 11/0625; G03F 1/84

(57) ABSTRACT

A boundary detector detects a boundary between a transparent plate and a frame. The boundary detector includes a light source, a shield and two beam-adjusting units. The light source emits an original beam. The shield blocks secondary reflected beam and slits the original beam into a middle incident beam and two lateral incident beams. The middle incident beam gets reflected from the transparent plate and becomes a middle reflected beam. The lateral incident beams get reflected from two lateral portions of the frame and become two lateral reflected beam. The beam-adjusting units direct the lateral incident beams. The intensity of the middle reflected beam is different from that of the lateral reflected beams so that the boundary is detected.

### BACKGROUND OF INVENTION

### 1. Field of Invention

The present invention relates to optical inspection of a mask used in lithograph and, more particularly, to a boundary detector used in an optical inspection apparatus.

### 2. Related Prior Art

A mask is a necessary element used in lithography for raking an integrated circuit (“IC”) on the surface of a wafer. The dimension of the wiring in an IC can be made smaller than 10 nanometers. Hence, any contamination on a mask in a process for making IC products could affect the yield of the production.

Referring to FIG. 1, a mask 100 includes a substrate 110, a pattern layer 115, a frame 120 and a pellicle 150. The substrate 100 is made of a transparent material such as quartz and glass. The pellicle 150 protects the pattern layer 115 from contaminants such as particles, stains or volatile gases. However, there are inevitably contaminants such as the one marked as A on a face 112 of the substrate 110 and contaminants such as the one marked as B on a face 151 of the pellicle 150.

Referring to FIG. 2, a conventional mask-inspecting apparatus includes a light source L and a photo sensor C such as a charge-coupled device (“CCD”) or a complementary metal-oxide semiconductor (“CMOS”). The light source L casts a beam (the “incident beam”) Lo onto a face 112 of the substrate 110. The face 112 reflects the incident beam Lo and transmits reflected beam Lr (the “primary reflected beam Lr1”) to the photo sensor C. There is an incident angle θ1 between the incident beam Lo and a normal line In of the face 112, and there is a reflection angle θ2 between the primary reflected beam Lr1 and the normal line In of the face 112. The incident angle θ1 is substantially identical to the reflection angle θ2. The photo sensor C receives and processes the primary reflected beam Lr1 from the face 112 to detect any contaminant on the face 112.

However, according to Snell's Law, some of the incident beam Lo (the “beam Lc”) goes through the face 112 and gets refracted, and then reaches a face 111 of the substrate 110. Some of the beam Lc gets reflected from the face 111. Some of the beam reflected from the face 111 gets refracted by the face 112 and becomes secondary reflected beam Lr2. Such a process continues until the beam is too weak to be detected by the photo sensor C.

There are superimposed images because the photo sensor C receives the secondary reflected beam Lr2 or any other beam reflected from the face 111 and refracted by the face 112 in addition to the primary reflected beam Lr1. For example, the contaminant A is on the face 112 of the substrate 110, and the contaminant B is on the face 151 of the pellicle 150. The real state of contamination cannot be detected effectively because the images of the contaminants A and B are superimposed.

The images are processed to determine the real state of contamination. The boundary of the pellicle 150 should be detected to properly process the images. However, it is difficult to use a conventional optical inspection apparatus to detect the boundary of the face 151 of the pellicle 150.

The present invention is therefore intended to obviate or at least alleviate the problems encountered in prior art.

### SUMMARY OF INVENTION

It is the primary objective of the present invention to provide an optical inspection machine with a boundary detector for inspecting a laminate that includes a first layer and a second layer that extends below the first layer.

To achieve the foregoing objective, the boundary detector detects a boundary between a transparent plate and a frame. The boundary detector includes a light source, a shield and two beam-adjusting units. The light source emits an original beam. The shield blocks secondary reflected beam and slits the original beam into a middle incident beam and two lateral incident beams. The middle incident beam gets reflected from the transparent plate and becomes a middle reflected beam. The lateral incident beams get reflected from two lateral portions of the frame and become two lateral reflected beam. The beam-adjusting units direct the lateral incident beams. The intensity of the middle reflected beam is different from that of the lateral reflected beams so that the boundary is detected.

Other objectives, advantages and features of the present invention will be apparent from the following description referring to the attached drawings.

### BRIEF DESCRIPTION OF DRAWINGS

The present invention will be described via detailed illustration of the preferred embodiment in view of the prior art referring to the drawings wherein:

FIG. 1 is a cross-sectional view of a typical mask;

FIG. 2 is a front view of a conventional optical apparatus for inspecting the mask shown in FIG. 1;

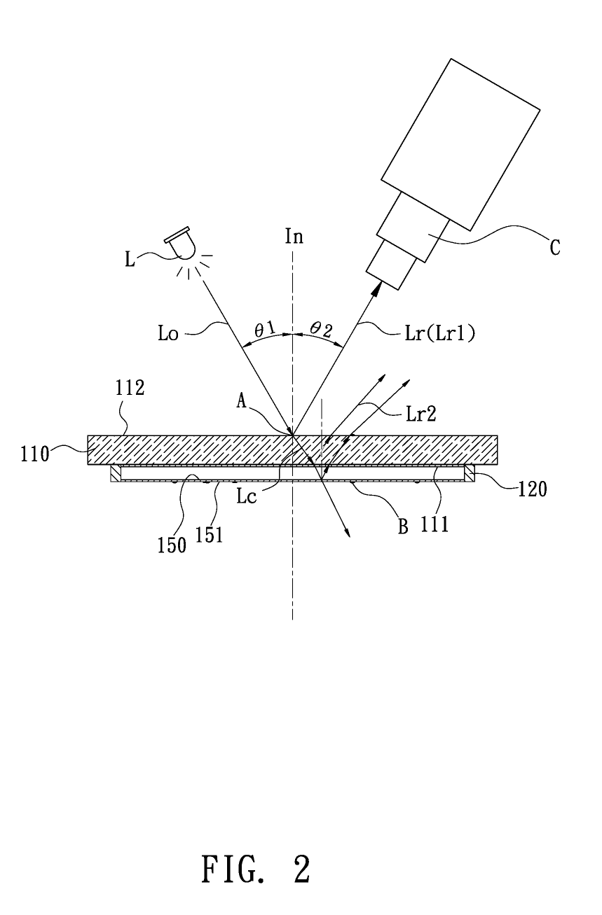

FIG. 3 is a perspective view of a boundary detector according to the preferred embodiment of the present invention;

FIG. 4 is an exploded view of the boundary detector shown in FIG. 3;

FIG. 5 is another perspective view of the boundary detector shown in FIG. 3, showing beams in operation;

FIG. 6 is a cross-sectional view of the boundary detector of FIG. 5 working on a pellicle supported on a frame of the mask shown in FIG. 1;

FIG. 7 is another cross-sectional view of the boundary detector shown in FIG. 6; and

FIG. 8 is a cross-sectional view of a mask-inspecting apparatus using two boundary detectors as the one shown in FIG. 5.

### DETAILED DESCRIPTION OF PREFERRED EMBODIMENT

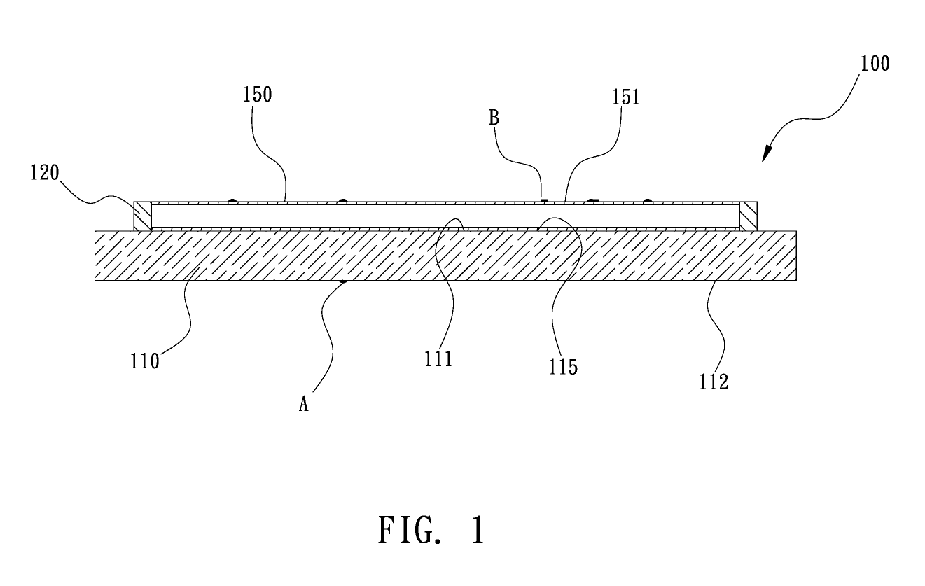

As discussed above in the RELATED PRIOR ART referring to FIG. 1, a typical mask 100 includes a substrate 110, a pattern layer 115, a frame 120 and a pellicle 150. The substrate 110 is made of a transparent material such as quartz and glass, and includes two faces 111 and 112. The frame 120 is made of an opaque material. The frame 120 is supported on the face 111. The pellicle 150 includes a face 151. The pellicle 150 is supported on the frame 120. The frame 120 extends along the boundary of the pellicle 150. The face 111 and the face 151 extend at different heights.

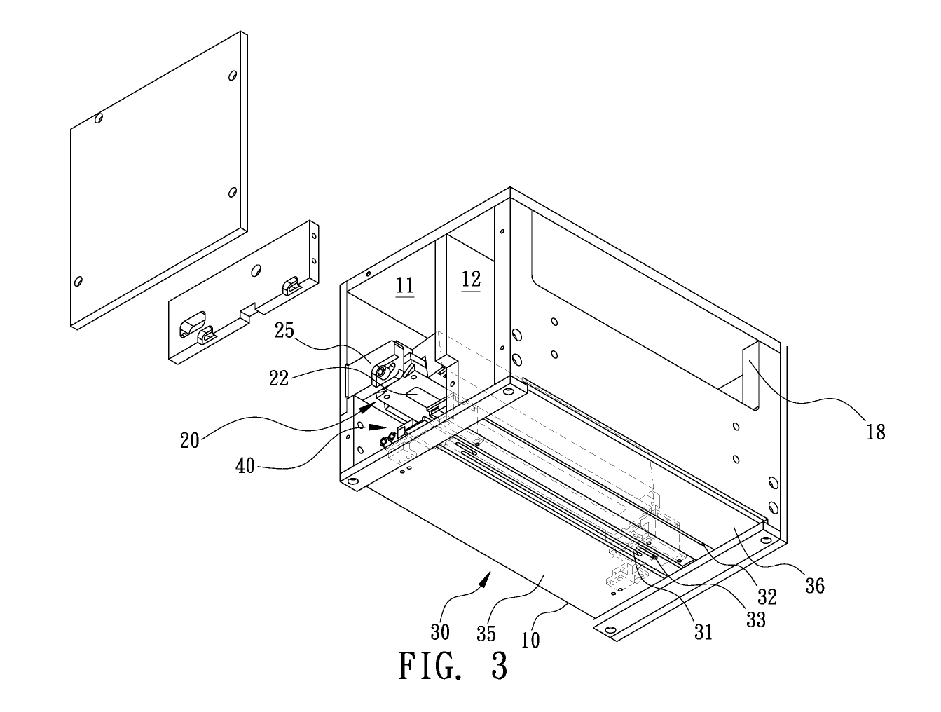

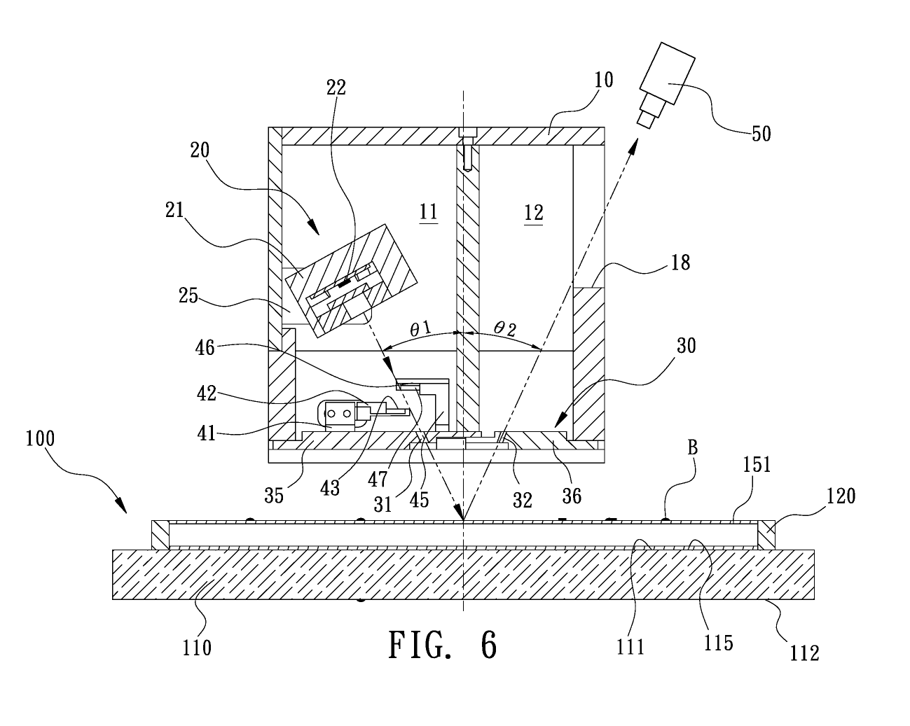

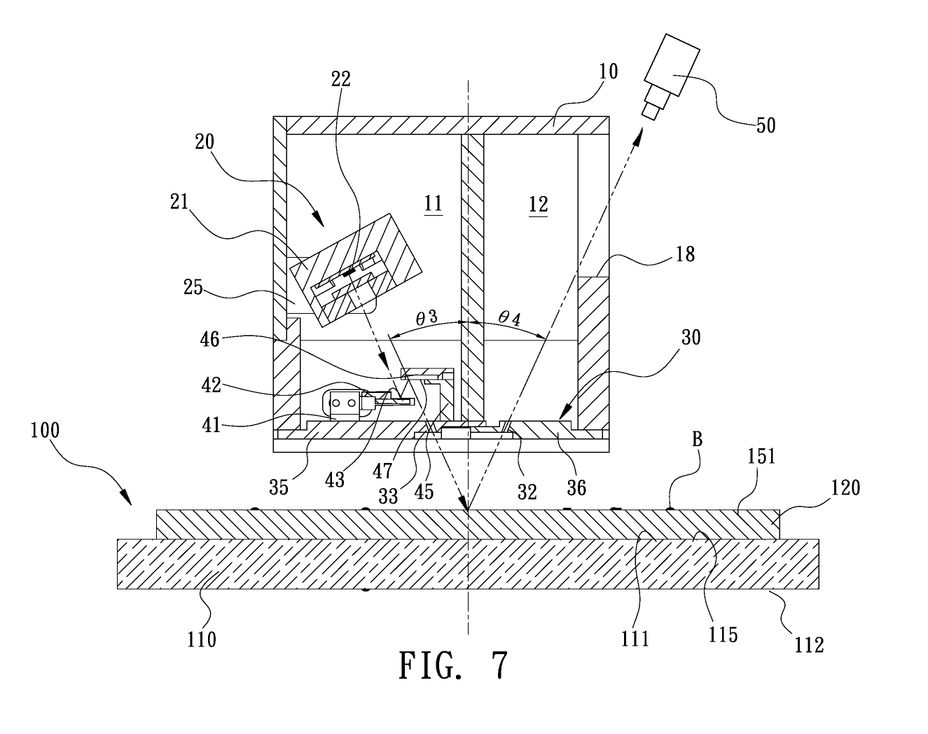

Referring to FIGS. 3 to 7, a boundary detector includes a case 10, a light source 20, a shield 30 and two beam-adjusting units 40 according to the preferred embodiment of the present invention can be used to inspect the mask 100. The boundary detector is used to inspect the face 112 of the substrate 110 and the face 151 of the pellicle 150.

The light source 20 casts an incident beam onto the face 112 of the substrate 110 when used to inspect the face 112 of the substrate 110. The incident beam reaches the faces 112 and 111 of the substrate 110 and gets reflected, thereby providing a primary reflected beam and at least one secondary reflected beam. The shield 30 blocks the secondary reflected beam. Later, the primary reflected beam is received by an image sensor 50.

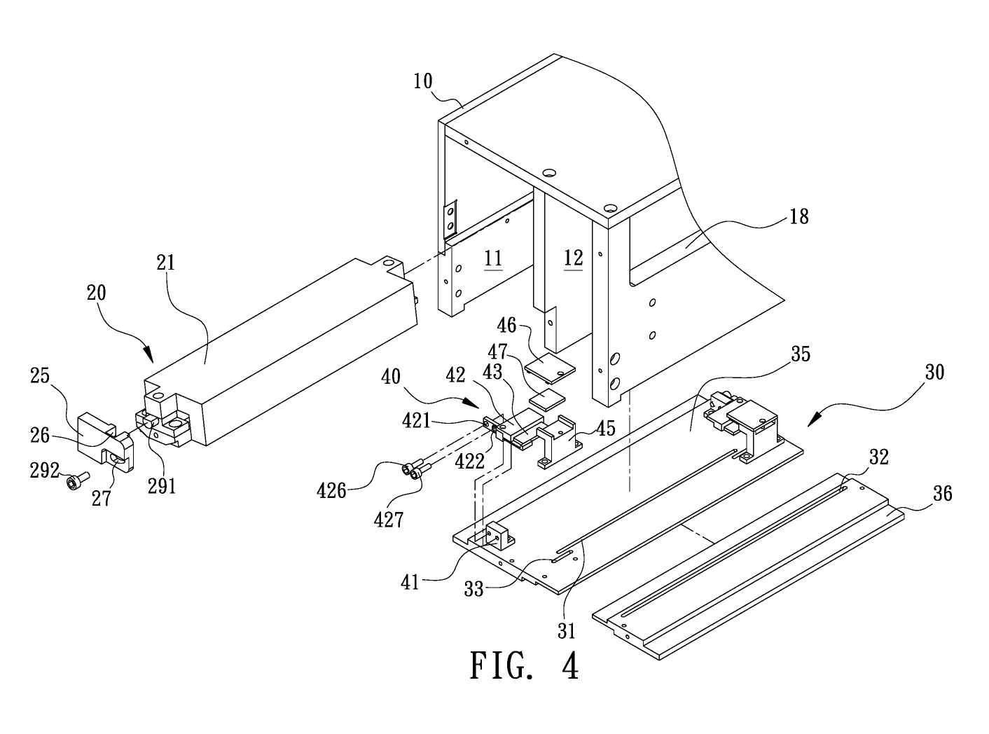

Referring FIGS. 3 and 4, the boundary detector preferably includes a case 10 for containing the light source 20, the shield 3 and the beam-adjusting units 40. The case 10 is made of opaque plates and includes two separated chambers 11 and 12. Preferably, the case 10 is made in one piece, and the shield 30 is attached to a lower portion of the case 10 to close open lower ends of the chambers 11 and 12. Alternatively, the chamber 11 is made in a subcase, and the chamber 12 in another subcase, and the subcases are connected to each other to form the case 10. Alternatively, the subcases are separated from each other. The chamber 12 includes a window 18 in a wall of the case 10 opposite to the chamber 11.

The light source 20 is inserted in the chamber 11 of the case 10. The light source 20 includes a light emitter 22 inserted in a shell 21. The light emitter 22 provides a beam with a certain width. The light emitter 22 emits visible or invisible light. The light emitter 22 is a halogen lamp, an LED, a high-frequency fluorescent lamp, a metal light bulb, a neon lamp or a laser lamp for example. The image sensor 50 such as CCD and CMOS must be able to detect the beam emitted from the light emitter 22. The shell 21 of the light source 20 is supported on two brackets 25 attached to an internal face of the chamber 11 of the case 10. Each of the brackets 25 includes axial aperture 26 and coaxial arched slot 27. The shell 21 includes an axle 291 inserted in the axial aperture 26. A fastener 292 is inserted in the shell 21 through the arched slot 27. Thus, the shell 21 can be located in various angles relative to the brackets 25. Hence, the light emitter 22 can cast a beam at different angles.

The shield 30 is attached to a lower portion of the case 10 to cover an open lower end of the chamber 11 and an open lower end of the chamber 12. The shield 30 includes an exit 31 in communication with the chamber 11 and an entrance 32 in communication with the chamber 12. The exit 31 is in the form of a slot, and so is the entrance 32. The beam emitted from the light source 20 goes to an inspected face via the exit 31 and gets reflected from the inspected face. The reflected beam goes into the chamber 12 through the entrance 32. Then, the reflected beam goes out of the chamber 12 through the window 18. Finally, the reflected beam reaches the image sensor 50, which is located out of the case 10.

The shield 30 further includes two slots 33, with each of the slots 33 in the vicinity of a corresponding end of the exit 31. The distance between the axis of the exit 31 and that of the slots 33 is identical to the distance between the face 151 of the pellicle 150 and the face 111 of the substrate 110. The slots 33 extend for 5 to 20 mm. The distance between the centers of the slots 33 is identical to a width of the face 151 of the pellicle 150.

The width of the exit 31 is substantially identical to that of the slots 33. The width of the exit 31 and the width of the slots 33 are preferably 0.1 to 5 mm, smaller than that of the entrance 32. The width of the exit 31, the width of the slots 33 and the width of the entrance 32 are smaller than the thickness of the substrate 110.

Preferably, the positions of the exit 31 and the entrance 32 are adjustable. To this end, the shield 30 includes two plates 35 and 36. The exit 31 and the slots 33 are made in the plate 35. The entrance 32 is made in the plate 36. The case 10 further include two planks 39 on two opposite sides of the shield 30. The plates 35 and 36 are movably supported on the planks 39 so that the positions of the plates 35 and 36 are adjustable. Therefore, the angle of the incident beam onto the substrate 110 and the angle of the reflected beam from the substrate 110 are adjustable.

The beam-adjusting units 40 are inserted in the chamber 11, above the shield 30. Each of the beam-adjusting units 40 includes a tab 41, a mount 42, two reflectors 43 and 47, a supporting element 45 and a board 46. The following description will be given to only one of the beam-adjusting units 40 for clarity. The reflectors 43 and 47 guide the beam emitted from the light source 20 through a corresponding one of the slots 33 of the shield 30. The tab 41 is supported on the plate 35, near a corresponding one of the slots 33. The mount 42 is supported on the tab 41. The reflector 43 is connected to the mount 42. The mount 42 includes an axial aperture 421 and an arched slot 422. Two fasteners 426 and 427 are inserted in tab 41 via the axial aperture 421 and the coaxial arched slot 422, respectively. For the use of the axial aperture 421 and the arched slot 427, the angle of the reflector 43 relative to the light emitter 22 is adjustable. The supporting element 45 is supported on the shield 30 so that the corresponding slot 33 is located between the mount 42 and the supporting element 45. The board 46 is movable on the supporting element 45. The reflector 47 is attached to a lower face of the board 46. The reflector 47 reflects the beam reflected form the reflector 43, thereby guiding the reflected beam out of the case 10 via the corresponding slot 33.

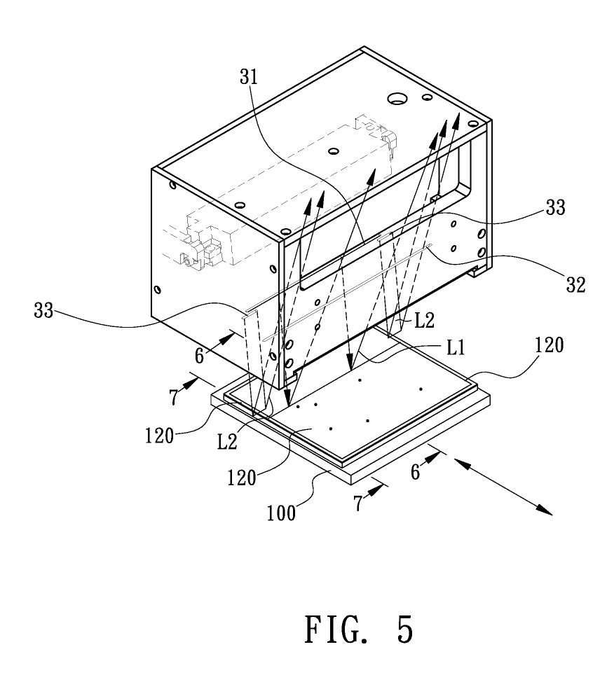

Referring to FIGS. 5 through 7, the boundary detector is used to scan the boundary of the face 151 of the pellicle 150. As mentioned above, the pellicle 150 is supported on the face 111 of the substrate 110 by the frame 120. The face 151 of the pellicle 150 is substantially flush with a face of the frame 120.

In the chamber 11, the light emitter 22 emits a beam (the “original beam”). A middle portion of the original beam travels out of the chamber 11 through the exit 31 and becomes a middle incident beam. Two lateral portions of the original beam get reflected by the beam-adjusting units 40 and travel out of the chamber 11 via the slots 33 and become two lateral incident beams.

The middle incident beam is cast on and reflected from the face 151 of the pellicle 150, thus providing a middle reflected beam. Each of the lateral incident beams is cast on and reflected from a lateral portion of the frame 120 and a lateral portion of the face 151 of the pellicle 150, thus providing a lateral reflected beam. The middle and lateral reflected beams enter the chamber 12 through the entrance 32, and then travel out of the chamber 12 via the window 18. Finally, the middle and lateral reflected beams reach the image sensor 50. An image is produced according to the middle and lateral reflected beams. Due to the width of the exit 31 and the entrance 32, not any secondary reflected beam from the face 151 of the pellicle 150 and the face of the frame 120 can enter the chamber 12 via the entrance 32.

The middle incident beam is cast on the face 151 at an angle θ1 and gets reflected from the face 151 at an angle θ2. Each of the lateral incident beams is cast on the corresponding lateral portion of the frame 120 at an angle θ3 and gets reflected from the corresponding lateral portion of the frame 120 at an angle θ4. The angle θ1 is substantially identical to the angle θ2. The angle θ3 is substantially identical to the angle θ4. The angle θ2 is however different from the angle θ4. Hence, the intensity of the middle reflected beam from the pellicle 150 is different from that of the lateral reflected beams from the frame 120.

The image based on the middle and lateral reflected beams includes a middle portion, two lateral portions and two superimposed portions. The middle portion of the image is obtained from the middle reflected beam and only covers the face 151. Each of the lateral portions of the image is obtained from the corresponding lateral reflected beam and only covers the corresponding lateral portion of the frame 12. Each of the superimposed portions of the image is obtained from the middle reflected beam and the corresponding lateral reflected beam and covers the corresponding lateral portion of the face 151 and the corresponding lateral portion of the frame 12. Then, the image is processed to determine the boundary of the face 151 of the pellicle 150. The precise determination of the face 151 is used to obtain the real state of contamination. Hence, the boundary detector increases precision and reduces the risks of misjudgment.

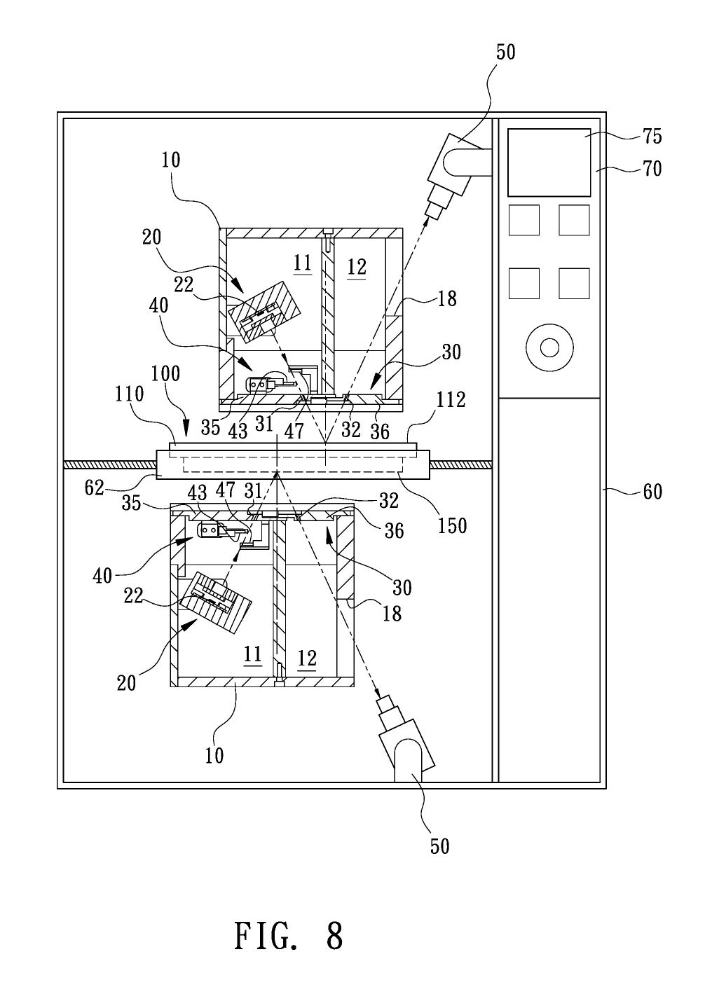

Referring to FIG. 8, an optical inspection machine 60 includes two boundary detectors as the one described referring to FIGS. 3 to 7. The optical inspection machine 60 includes a worktable 61, a carrier 62 movable on the worktable 61 in a rectilinear manner includes, and two optical modules. The mask 100 is supported on the carrier 62. Each of the optical modules includes a boundary detector 10 and an image sensor 50. One of the optical modules is located above the worktable 61 to inspect the face 112 of the substrate 110. The other optical module is located below the worktable 61 to inspect the face 151 of the pellicle 150. The image sensors 50 receive the beam from the cases 10 via the windows 18. The light sources 20 and the image sensors 50 are electrically connected to a processor 70 operable for calculation, comparison and analysis. The processor 70 includes a display 75. The processor 70 is operable to control the intensity of the beam emitted from the light emitter 22, and provide images of the mask 100 on the display 75 based on the reflected beam received by the image sensor 50. Hence, the size, shape and type of any contaminant can be determined to facilitate removing of the contaminant in a proper manner

The present invention has been described via the illustration of the preferred embodiment. Those skilled in the art can derive variations from the preferred embodiment without departing from the scope of the present invention. Therefore, the preferred embodiment shall not limit the scope of the present invention defined in the claims.

1. A boundary detector for detecting a boundary between a transparent plate and a frame, the boundary detector comprising:
a light source (20) for emitting an original beam;
a shield (30) for blocking secondary reflected beam and splitting the original beam into a middle incident beam and two lateral incident beams, wherein the middle incident beam gets reflected from the transparent plate and becomes a middle reflected beam, wherein the lateral incident beams get reflected from two lateral portions of the frame and become two lateral reflected beams; and
two beam-adjusting units (40) operable to direct the lateral incident beams, wherein the intensity of the middle reflected beam is different from that of the lateral reflected beams so that the boundary is detected.

2. The boundary detector according to claim 1, further comprising an opaque case (10) comprising a first chamber (11) and a second chamber (12), wherein the shield (30) is attached to a lower portion of the case (10) to cover open lower ends of the first and second chambers (11, 12), wherein the light source (20) is located in the first chamber (11), wherein the case (10) comprises a window (18) in a wall thereof opposite to the first chamber (11), wherein the window (18) is in communication with the second chamber (12) so that the primary reflected beam goes out of the chamber (12) via the window (18).

3. The boundary detector according to claim 1, wherein the light source (20) comprises shell (21) and a light emitter (22) located in the shell (21).

4. The boundary detector according to claim 3, wherein the light source (20) further comprises two brackets (25) attached to a wall of the first chamber (11), wherein the shell (21) is pivotally supported on the brackets (25).

5. The boundary detector according to claim 4, wherein each of the brackets (25) comprises an axial aperture (26) and arched slot (27) coaxial with the axial aperture (26), wherein the light source (20) further comprises axle (291) inserted in the shell (21) through the axial aperture (26) and a fastener (292) inserted in the shell (21) through the arched slot (27).

6. The boundary detector according to claim 2, wherein the shield (30) comprises:
an exit (31) in communication with the first chamber (11) so that the middle incident beam goes out of the first chamber (11) through the exit (31) of the shield (30); and
an entrance (32) in communication with the second chamber (12) so that the primary reflected beam goes into the second chamber (12) via the entrance (32); and
two slots (33) near two ends of the exit (31) so that the beam reflected from the boundary goes out of the first chamber (11) via the exit (31).

7. The boundary detector according to claim 6, wherein the shield (30) comprises a first plate (35) and a second plate (36), wherein the exit (31) and the slots (33) are made in the first plate (35), wherein the entrance (32) of the shield (30) is made in the second plate (36).

8. The boundary detector according to claim 7, the shield (30) further comprises two planks (39) connected to the case (10) and used to restrain the planks (39).

9. The boundary detector according to claim 6, wherein the beam-adjusting units (40) are located in first chamber (11) near the light source (20), wherein each of the beam-adjusting units (40) comprises a first reflector (43) and a second reflector (47) operable to direct the corresponding lateral incident beam out of the first chamber (11) via the corresponding slot (33).

10. The boundary detector according to claim 9, wherein the beam-adjusting unit comprises:
a tab (41) supported on the shield (30), in the first chamber (11);
a mount (42) supported on the tab (41),wherein the first reflector (43) is supported on the mount (42);
a supporting element (45) supported on the shield (30), in the first chamber (11) so that the exit (31) of the shield (30) is located between the supporting element (45) and the tab (41); and
a board (46) supported on the supporting element (45), wherein the second reflector (47) is attached to a lower face of the board (46).

11. The boundary detector according to claim 10, wherein the mount (42) comprises an axial aperture (421) and an arched slot (422) coaxial with the axial aperture (421), wherein the beam-adjusting unit further comprises a fastener (426) inserted in the tab (41) through the axial aperture (421) and another fastener (427) inserted in the table (41) through the arched slot (422).

12. An optical inspection machine comprising:
a worktable (61);
a carrier (62) movably supported on the worktable (61) and operable to carry an object to be inspected;
at least one optical module on a side of the worktable (61) and comprising an image sensor (50) and the boundary detector according to claim 1, wherein the image sensor (50) receives the primary reflected beam from the second layer (110) and the beam reflected from the boundary of the upper face (151) of the first layer (150); and
a processor (70) electrically connected to the boundary detector and the image sensor (50) and operable to calculate the intensity of the primary reflected beam and the beam reflected from the boundary, wherein the processor (70) comprises a display (75) for providing images of the upper face (112) of the second layer (110) and the upper face (151) of the first layer (150) according to the reflected beams.
